(19) United States
(12) Patent Application Publication
(10) Pub. No.: US 2013/0075247 A1
(43) Pub. Date: Mar. 28, 2013

(54) METHOD AND SYSTEM FOR FORMING CHALCOGENIDE SEMICONDUCTOR MATERIALS USING SPUTTERING AND EVAPORATION FUNCTIONS

(71) Applicants: Wen-Chin Lee, Baoshan Township (TW); Wen-Tsai Yen, Caotun Township (TW); Yung-Sheng Chiu, Hsinchu City (TW); Ying Chen Chao, Hsinchu City (TW)

(72) Inventors: Wen-Chin Lee, Baoshan Township (TW); Wen-Tsai Yen, Caotun Township (TW); Yung-Sheng Chiu, Hsinchu City (TW); Ying Chen Chao, Hsinchu City (TW)

(73) Assignee: TAIWAN SEMICONDUCTOR MANUFACTURING CO., LTD., HSIN-CHU (TW)

(21) Appl. No.: 13/239,989

(22) Filed: Sep. 22, 2011

(51) Int. Cl. C23C 14/34

(52) U.S. Cl. 204/192.25; 204/298.02; 204/298.04; 257/E31.027

(57) ABSTRACT

A method and system for forming a chalcogenide or chalcopyrite-based semiconductor material provide for the simultaneous deposition of metal precursor materials from a target and Se radials from a Se radical generation system. The Se radical generation system includes an evaporator that produces an Se vapor and a plasma chamber that uses a plasma to generate a flux of Se radicals. Multiple such deposition operations may take place in sequence, each having the deposition temperature accurately controlled. The deposited material may include a compositional concentration gradient or may be a composite material, and may be used as an absorber layer in a solar cell.

### TECHNICAL FIELD

The disclosure relates, most generally, to the formation of thin films. More particularly, the disclosure relates to forming chalcogenide semiconductor materials using hybrid vacuum deposition equipment.

### BACKGROUND

Chalcogenide semiconductor materials are used in many applications and their popularity is increasing in recent years. A chalcogenide is a binary compound of a chalcogen and a more electropositive element or radical. Chalcogens are the group 16 elements of the periodic table: oxygen, sulfur, selenium, tellurium, and polonium. One particularly popular chalcogenide semiconductor material is CIGS, copper indium gallium selenide. CIGS materials find use in various applications and are particularly popular as absorber layers for solar cells. Due to the growing demand for clean sources of energy, the manufacture of solar cells has expanded dramatically in recent years, increasing the demand for CIGS and other chalcogenide materials. CIGS is a tetrahedrally bonded semiconductor, with a chalcopyrite crystal structure. Other chalcogenide materials may also include chalcopyrite crystal structures.

Solar cells are photovoltaic components for direct generation of electrical current from sunlight. The absorber layer that absorbs the sunlight that will be converted into electrical current, is therefore of paramount importance. The formation of the absorber layer and the placement of the same on a solar cell substrate is therefore a critical operation. As such, the demand for the efficient, accurate and reliable production of such a film is of growing and critical importance.

It would therefore be desirable to produce a high quality chalcogenide film using a method and system that produce smooth and uniform deposited chalcogenide films with surfaces having substantially large grain sizes. It would also be desirable to produce a high quality chalcogenide film using a method and system that exhibit superior run-to-run reproducibility and which do not suffer from target poisoning, arcing or other process instabilities brought about by contamination of the chamber.

### BRIEF DESCRIPTION OF THE DRAWING

The present disclosure is best understood from the following detailed description when read in conjunction with the accompanying drawing. It is emphasized that, according to common practice, the various features of the drawing are not necessarily to scale. On the contrary, the dimensions of the various features may be arbitrarily expanded or reduced for clarity. Like numerals denote like features throughout the specification and drawing.

FIG. 1 is a flowchart of an exemplary method of the disclosure;

FIG. 2 schematically illustrates an exemplary hybrid deposition apparatus of the disclosure;

FIG. 3 schematically illustrates an exemplary embodiment of an Se radical generation unit according to the disclosure; and

FIGS. 4A-4D are cross-sectional views illustrating an exemplary sequence of processing operations for forming a chalcogenide film according to an exemplary embodiment of the disclosure.

### DETAILED DESCRIPTION OF EMBODIMENTS OF THE DISCLOSURE

The disclosure provides a method and system for forming chalcogenide semiconductor material layers. In addition to the CIGS, copper indium gallium selenide chalcogenide discussed supra, other chalcogenide semiconductor materials include CuInSe₂, CuGaSe₂, and indium. The aforementioned and other chalcogenide semiconductor materials are semiconductors with a chalcopyrite structure and are therefore often referred to as chalcopyrite-based semiconductor materials or chalcopyrite-structured semiconductor materials.

Chalcogenide semiconductor material layers may be used as absorber layers in solar cells. In one exemplary embodiment, the chalcogenide semiconductor material layer may be the only absorber layer in a solar cell and according to other exemplary embodiments, the chalcogenide semiconductor material layer may be used in conjunction with an additional absorber layer such as chalcopyrite (CuFeS₂) or other suitable absorber materials used in solar cells. According to other exemplary embodiments, the chalcogenide, i.e. chalcopyrite-based semiconductor material, may be used in other applications related or unrelated to solar cells. Hereinafter, chalcogenide semiconductor materials may be referred to alternatively as chalcopyrite-based semiconductor materials.

Methods and systems for forming chalcogenide semiconductor materials generally involve a growth process that involves the selenization of binary or ternary alloy precursors. This selenization may utilize Se vapor or an H₂Se/Ar gas mixture to form chalcogenide semiconductor materials. An evaporation process may generate SE vapor or an H₂Se/Ar gas mixture and a sputtering process may be utilized in conjunction with the Se vapor or H₂Se/Ar gas mixture to deposit the chalcogenide materials.

One exemplary method and system provide for the dissociation or cracking of selenium into selenium radicals. A selenium source may be thermally evaporated to produce a selenium vapor which is then cracked, i.e. dissociated, to form selenium free-radicals. The method and apparatus provide for simultaneously performing a sputtering operation and directing the Se radicals to a substrate along with the sputtered material to form a binary or ternary chalcogenide film that includes selenium, such as CIGS, which may be used as a light absorber material in photovoltaic cells, i.e., solar cells or in other applications. CIGS may be expressed as a solid solution of copper indium selenide and copper gallium selenide represented by a chemical formula of CulnₓGa₍₁₋ₓ₎Se₂ where the value of x can vary from one to zero.

In other exemplary embodiments, the method and system may be used to form other chalcogenide materials such as copper indium selenide or copper gallium selenide or other materials that are of interest for photovoltaic applications particularly in the form of polycrystalline thin films.

The method and apparatus provide a hybrid deposition tool with multiple stations including one or more sputter or evaporation stations that include a metal or metallic alloy target and at least one station that produces a plasma generated flux of Se radicals.

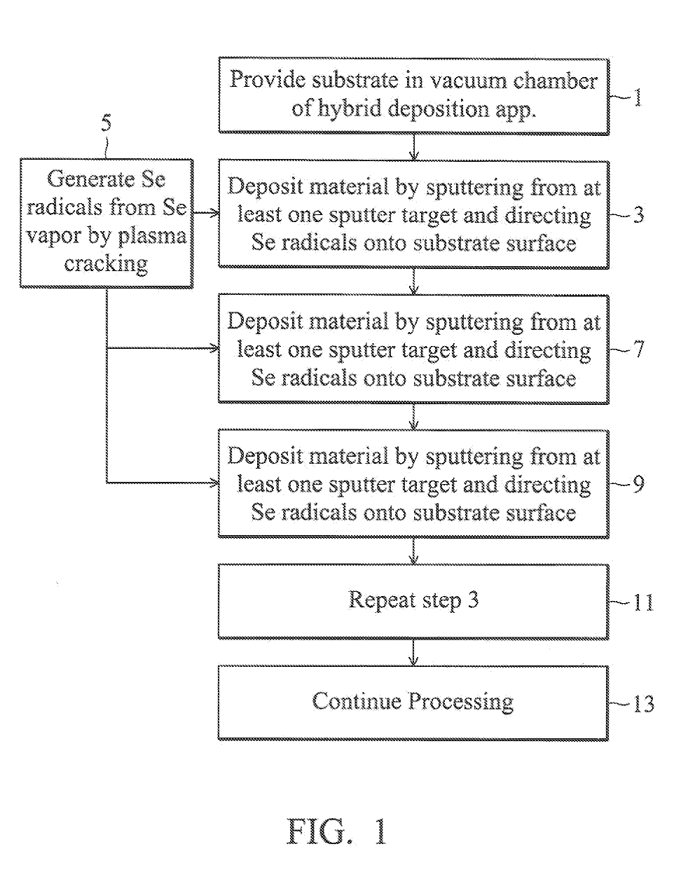

FIG. 1 is a flowchart showing an exemplary method of the disclosure and steps 1-11 of the illustrated method may be carried out in a single hybrid deposition apparatus. More particularly, FIG. 1 provides an overview of an exemplary process which is described in further detail below. At step 1, a substrate is provided in a vacuum chamber of a hybrid deposition apparatus. The hybrid deposition apparatus includes multiple sputter deposition stations and at least one evaporative station that generates Se radicals. At step 3, a material layer is formed/deposited onto a substrate surface by simultaneously sputtering material from at least one sputtering target while also directing Se radicals onto the substrate surface. The Se radicals are generated from a selenium vapor by plasma cracking as indicated in step 5. At steps 7 and 9, a material layer is deposited as indicated and the sequential deposition operations that take place in steps 3, 7 and 9 may represent sequential sputtering operations whereby different sputtering targets of the hybrid deposition apparatus are used for each of the different sputtering operations. This sequential sputtering is performed while simultaneously directing the Se radicals onto the substrate, without removing the substrate from the vacuum chamber. At optional step 11, another deposition step involving the sputtering of material from a sputtering target or targets together with the simultaneous deposition of selenium radicals, may be utilized. Various exemplary embodiments may utilize various numbers of sequential deposition operations. The sequential deposition operations may form a composite film that comprises a number of individual layers having the same, or different compositions, or the sequential deposition operations may form a material with a compositional gradient. A heating operation may follow the deposition steps. At step 13, further processing continues.

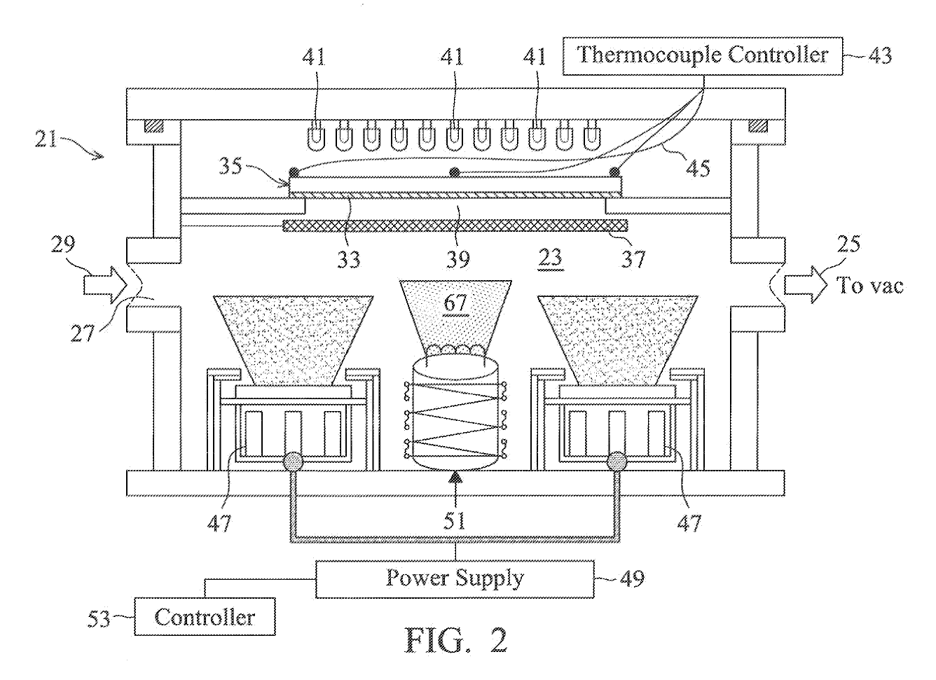

FIG. 2 is a schematic illustrating an exemplary system of the disclosure. Hybrid deposition apparatus 21 includes vacuum chamber 23 which may be evacuated by a vacuum such as indicated by arrow 25. Various sputtering gases such as Argon or other inert gasses, may be introduced to vacuum chamber 23 at inlet 27 as indicated by gas flow arrow 29. Substrate 33 is retained on stage 35 which may be an electrostatic chuck, or other suitable chuck according to various exemplary embodiments. Substrate 33 includes surface 39 upon which one or more films will be deposited when optional shutter 37 is in the open position. The temperature of various regions of stage 35 is controlled by the heating elements 41 of a heater block and controlled by temperature controller 43. Various different spatial locations of stage 35 may be separately controlled by temperature controller 43 as indicted by wires 45 that terminate at multiple different locations of stage 35. Heating elements 41 may be grouped in a manner that enables particular zones if stage 35 to be maintained at different temperatures, in some exemplary embodiments. Temperature controller 43 may include a thermocouple or other type of thermometer and is capable of detecting and controlling temperature at the different indicated spatial locations as desired during each of multiple deposition operations.

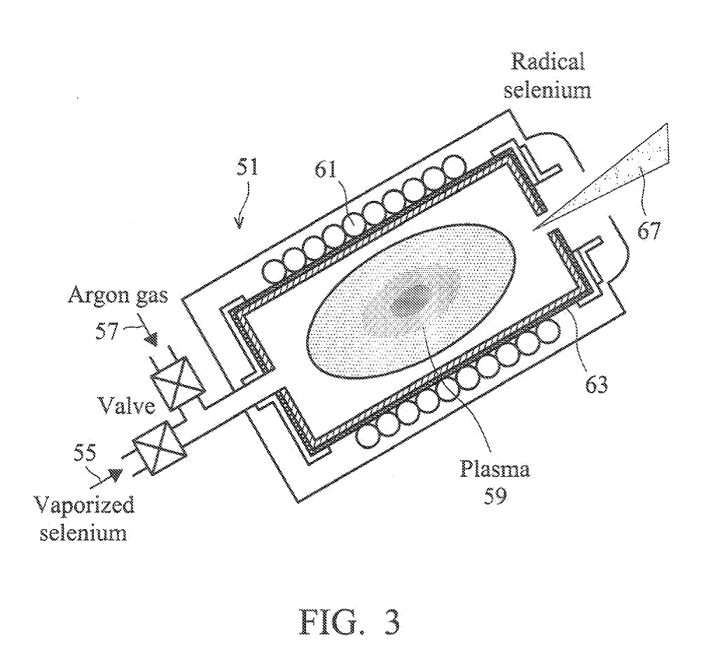

Hybrid deposition apparatus 21 also includes exemplary sputtering stations 47 and Se radical generation station 51. It should be understood that FIG. 2 is two-dimensional and that hybrid deposition apparatus 21 may include various numbers of sputtering stations 47 disposed in various orientations and capable of sputtering material onto surface 39 of substrate 33. The configuration of sputtering stations 47 is exemplary only. Sputtering stations 47 are coupled to a DC or RF power supply 49 and in one exemplary embodiment, DC or RF power supply 49 may be a pulsed DC or RF power supply. Each sputtering station 47 includes a sputtering target and may be an RF magnetron sputtering system in various exemplary embodiments. The sputtering stations 47 may be controllable by a controller such as controller 53 and in one exemplary embodiment, a sequence of sputtering operations may be carried out to produce a deposited film that is a composite film or may be a film with a compositional gradient. Each of the sputtering operations may involve the operations of one or more sputtering stations such as sputtering stations 47. The sputtering targets utilized may represent various metals or various alloys such as but not limited to copper, Cu, indium, In, gallium, Ga, CuGa, In₂Se₃, Ga₂Se₃, CuInGa, or other suitable metal precursor compounds or alloys. Each of the sputtering operations takes place by supplying power to the appropriate sputtering station or stations 47 which causes the deposition of material on surface 39 of substrate 33. During at least one or all of the sputtering operations, Se radicals are simultaneously directed to surface 39 of substrate 33 by way of Se radical generation system 51. Se radical generation system 51 is shown in more detail in FIG. 3. In other exemplary embodiments, metal evaporation stations may be used in place of one or more of the sputtering stations 47 and these evaporation stations may be operated simultaneously with Se radical generation system 51 to form a film on surface 39 of substrate 33.

FIG. 3 shows Se radical generation system 51 including plasma chamber 63. Within plasma chamber 63, vaporized selenium is dissociated, i.e. cracked and converted to selenium radicals. Vaporized selenium 55 may be a thermally evaporated selenium vapor produced by known and other methods from various starting materials. Molecular evaporates such as Se₂, Se₃ and Se₄ may be produced by an evaporator such as one maintained at 380° C. but other vaporization temperatures may be used in other exemplary embodiments. Se powder or Se solids in pellet form may be used as the source of Se but other starting materials may be used in other exemplary embodiments. Vaporized selenium 55 is delivered to plasma chamber 63. Inert gas 57 may also be delivered through the indicated valve to plasma chamber 63 as in the illustrated embodiment. Inert gas 57 may be Argon as in the illustrated exemplary embodiment. Alternatively, other inert gasses may be used or the vaporization may take place in a vacuum. Plasma 59 is generated by various suitable means such as, but not limited to, radio frequency (RE) or microwave means. In another exemplary embodiment, the plasma may be generated in a vacuum or in a controlled atmosphere using ion bombardment by ion beams such as produced using ion beam assisted deposition (IBAD) techniques with low power settings. In one exemplary embodiment, coils 61 may be RF coils that generate the plasma, more particularly a plasma generated flux of radical selenium species is generated in plasma chamber 63. Se radicals 67 are generated and directed from Se radical generation system 51 toward the substrate.

Now returning to FIG. 2, Se radicals 67, represented by the shaded area in FIG. 2, are also directed to surface 39 of substrate 33 simultaneous with the deposition of sputter material from one or more of the sputter targets of sputtering stations 47.

In each case, the deposition operation involves the formation of a film on surface 39 of substrate 33, the film including material simultaneously sputtered from at least one sputtering station 47 while Se radicals 67 are generated and provided by Se radical generation system 51.

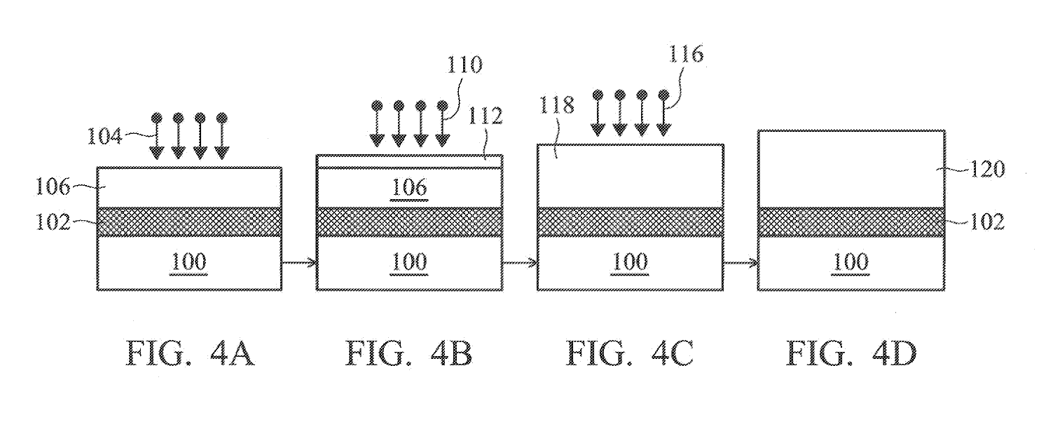

FIGS. 4A-4D are cross-sectional views showing the sequential multi-layered deposition of metallic precursors simultaneous with the deposition of Se radicals to form a gradient film. FIG. 4A shows substrate 100 which may be a semiconductor material or it may be glass, such as in the solar cell manufacturing industry. Contact layer 102 is formed over substrate 100 to provide ohmic contact and may be formed of black silicon or other suitable materials such as, but not limited to Mo, Pt, Au, Cu, Cr, Al, Ca, Ag or Sno2, In2O3:Sn (ITO), In2O2:Ga, In2O3, Cd2SnO4 (CTO), Zn2SnO4, fluorine doped tin oxide (FTO), zinc oxide (ZnO) doped with group III elements such as aluminum-doped zinc oxide (ZnO:Al, AZO), and indium-doped cadmium oxide, in various exemplary embodiments. This is exemplary only and in other exemplary embodiments, various other films may be present or contact layer 102 may be absent. FIG. 4A shows materials 104 being deposited to form layer 106 over substrate 100. Materials 104 represent materials simultaneously sputtered from one or more sputtering stations 47 and from Se radical generation system 51. According to one exemplary embodiment, FIG. 4A represents a first step of a sequence of deposition operations and materials 104 may include indium, gallium and selenium with film 106 being expressed as (In,Ga)ₓSe_{y} but other films may be produced in other exemplary embodiments. Target materials such as In, In₂Se₃ and Ga₂Se₃ may be used as target materials in step 1. During the first deposition operation as illustrated in FIG. 4A, the temperature may be controlled and a temperature within the range of about 200°-325° C. may be used in one exemplary embodiment.

FIG. 4B represents a second deposition operation of sequential deposition operations. Materials 110 are deposited over film 106 to produce film 112. Materials 110 may include copper and selenium in one exemplary embodiment and film 112 may be expressed as Cu(In,Ga)Se₂ in one exemplary embodiment. Target materials that may be used to produce materials 110 may include Cu, CuGa or other suitable materials and one or more sputtering stations 47 may be used. During the second processing operation such as shown in FIG. 4B, the temperature may be controlled to a temperature within the range of about 450° C.-600° C. in one exemplary embodiment, but such is exemplary only.

FIG. 4C shows a subsequent deposition operation that also shows the effects of heating in steps 2 and 3 of the exemplary process sequence, i.e. FIGS. 4B and 4C. In FIG. 4C, film 118 is formed from films 106 and 112 and materials 116 which are being deposited from one or more sputtering stations 47 and as a result of the heating operations. In step 3, i.e. FIG. 4C, the temperature may be controlled to a temperature within the range of about 450-600° C. but other temperatures may be used in other exemplary embodiments. Materials 116 of deposition may include indium, gallium and selenium in one exemplary embodiment and may be sputtered from targets such as formed of indium, In₂Se₃ or Ga₂Se₃. Film 118 may be Cu(In,Ga)Se₂ in one exemplary embodiment. The heating that takes place during FIG. 4C or subsequent heating operation may alter the characteristics and produce film 120.

Film 120 is a chalcogenide film, i.e. a chalcopyrite-based semiconductor material. According to various exemplary embodiments, while the overall composition of film 120 may be Cu(In,Ga)Se₂ or other elemental combinations, film 120 may include concentration gradients of various components from top to bottom. In other embodiments, the film may be a composite film of distinguishable layers, i.e. layers of the same or different constituents that may be separated by distinguishable boundaries. In FIG. 4D, a heating operation may take place to produce the final compositional gradient of film 120 which may serve as an absorber layer of a solar cell in one exemplary embodiment. According to other exemplary embodiments, film 120 may be CuInSe₂ or CuGaSe₂. Film 120 is characterized by sufficiently large grain boundaries for use as photovoltaic materials, and also exhibit superior uniformity across the substrate upon which it is formed. The structure shown in FIG. 4D is then further processed to form final products such as photovoltaic, i.e. solar cells which utilize film 120 as an absorber layer or for other functions.

According to one aspect of the disclosure, a method for forming a layer of semiconductor material on a substrate is provided. The method comprises providing a substrate in an evacuable chamber of a film deposition apparatus and sputtering metal precursor materials from a plurality of sputtering targets onto the substrate while simultaneously directing Se radicals onto the substrate thereby forming an Se-based chalcogenide film on the substrate.

According to another aspect of the disclosure, a hybrid film formation apparatus is provided. The apparatus comprises a vacuum chamber with a stage for retaining a substrate upon which a film is deposited and at least one sputtering station for sputtering material onto the substrate, each sputtering station including a sputtering target and a power supply coupled thereto. The apparatus further comprises at least one Se station for producing Se radicals and causing the Se radicals to deposit onto the substrate and a controller that can control the at least one sputtering station and the at least one Se station to operate at the same time.

The preceding merely illustrates the principles of the disclosure. It will thus be appreciated that those skilled in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid in understanding the principles of the disclosure and the concepts contributed to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the disclosure has been described in terms of exemplary embodiments, it is not limited thereto. Rather, the appended claims should be construed broadly, to include other variants and embodiments of the disclosure, which may be made by those skilled in the art without departing from the scope and range of equivalents of the disclosure.

What is claimed is:

1. A method for forming a layer of semiconductor material on a substrate, said method comprising:
providing a substrate in an evacuable chamber of a film deposition apparatus; and
sputtering metal precursor materials from at least one sputtering target, onto said substrate while simultaneously directing Se radicals onto said substrate thereby forming an Se-based chalcogenide film on said substrate.

2. The method as in claim 1, wherein said sputtering comprises sequentially sputtering said metal precursor materials from a plurality of sputtering targets onto said substrate while simultaneously directing said Se radicals onto said substrate.

3. The method as in claim 2, wherein said sequentially sputtering comprises a plurality of sequential sputtering operations, said substrate is disposed on a stage and further comprising separately controlling temperatures of said stage during each said sequential sputtering operation.

4. The method as in claim 2, wherein said sequentially sputtering includes:
a first sputtering operation in which sputtering target is a first sputtering target that comprises at least one of In, In₂Se₃ and Ga₂Se₃;
a second sputtering operation in which said sputtering target is a second sputtering target that includes at least one of Cu and CuGa; and
a third sputtering operation in which said sputtering target is a third sputtering target that comprises at least one of In, In₂Se₃ and Ga₂Se₃.

5. The method as in claim 4, wherein said providing a substrate comprises disposing said substrate on a stage and further comprising controlling temperatures in said first sputtering operation to a temperature within a range of about 200-325° C. and controlling temperatures in said second and third sputtering operations to a temperature within a range of about 450-600° C.

6. The method as in claim 1, wherein said providing a substrate comprises disposing said substrate on a stage and further comprising separately controlling temperatures in multiple regions of said stage.

7. The method as in claim 1, wherein said substrate comprises a solar cell substrate and said Se-based chalcogenide film forms at least a portion of an absorber film.

8. The method as in claim 7, wherein said Se-based chalcogenide film comprises CuInGaSe.

9. The method as in claim 1, wherein said metal precursor materials include Cu, In, and Ga.

10. The method as in claim 1, further comprising cracking Se from a Se vapor source using a plasma to generate a flux of said Se radicals.

11. The method as in claim 10, wherein said using a plasma includes generating said plasma using RF.

12. The method as in claim 10, further comprising thermally evaporating a Se material to produce said Se vapor source.

13. The method as in claim 1, wherein said sputtering comprises pulsed reactive DC or RF magnetron sputtering.

14. A hybrid film formation apparatus comprising:
a vacuum chamber with a stage for retaining a substrate upon which a film is to be deposited;
at least one sputtering station for sputtering material onto said substrate, each said sputtering station including a sputtering target and a power supply coupled thereto;
at least one Se station for producing Se radicals and causing said Se radicals to deposit onto said substrate; and
a controller that controls said at least one sputtering station and said at least one Se station and can cause said at least one sputtering station and said at least one Se station to both operate at the same time.

15. The hybrid film formation apparatus as in claim 14, wherein said at least one sputtering station comprises a plurality of sputtering stations including a first sputtering station in which said sputtering target is a first sputtering target comprising a first target material including at least one of copper, indium, gallium and selenium and a second sputtering station in which said sputtering target is a second sputtering target comprising a second target material including at least one of said copper, gallium and indium.

16. The hybrid film formation apparatus as in claim 14, wherein said at least one sputtering station comprises a plurality of sputtering stations and said controller is configured for causing sequential operation of said plurality of sputtering stations while said Se radicals are deposited onto said substrate.

17. The hybrid film formation apparatus as in claim 14, further comprising a controllable heating element that heats said stage and wherein said controller causes said stage to achieve different temperatures during each of sequential sputtering operations.

18. The hybrid film formation apparatus as in claim 14, wherein said Se station includes a thermal evaporation chamber for forming Se vapor and a plasma station that produces said Se radicals from said Se vapor.

19. The hybrid film formation apparatus as in claim 18, wherein said plasma station includes one of an RF, an ion beam bombardment, and a microwave plasma generation system.

20. The hybrid film formation apparatus as in claim 14, wherein each said sputtering station includes a pulsed RF or DC system as a power supply.
